(19) United States
(12) Patent Application Publication
(10) Pub. No.: US 2014/0210073 A1
(43) Pub. Date: Jul. 31, 2014

(54) CONDUCTIVE PASTE, ELECTRODE FOR SEMICONDUCTOR DEVICE, SEMICONDUCTOR DEVICE, AND METHOD FOR MANUFACTURING SEMICONDUCTOR DEVICE

(71) Applicant: Satoshi Tanaka, Osaka-shi (JP)

(72) Inventor: Satoshi Tanaka, Osaka-shi (JP)

(73) Assignee: SHARP KABUSHIKI KAISHA, Osaka-shi, Osaka (JP)

(21) Appl. No.: 14/238,858

(22) PCT Filed: Aug. 28, 2012
(86) PCT No.: PCT/JP2012/071649

§ 371 Date: Feb. 14, 2014

(30) Foreign Application Priority Data
Aug. 31, 2011 (JP) 2011-188270

(51) Int. Cl. H01B 1/16; H01L 21/28; H01L 29/40

(52) U.S. Cl. CPC H01B 1/16; H01L 29/40; H01L 21/28
USPC 257/734; 438/661; 174/126.2; 252/514

(57) ABSTRACT

Provided is a conductive paste, an electrode for a semiconductor device manufactured by using the conductive paste, a semiconductor device and a method for manufacturing the semiconductor device. The conductive paste includes conductive powder made of a plurality of conductive particles and silver powder made of a plurality of silver particles. The conductive particles includes a base material made of ceramics and a conductive layer configured to cover at least a part of an outer surface of the base material. The ratio of the mass of the conductive layer relative to the total mass of the conductive particles is 10% or more by mass, and the ratio of the mass of the conductive powder relative to the total mass of the conductive powder and the silver powder is 25% or less by mass.

### TECHNICAL FIELD

The present invention relates to a conductive paste, an electrode for a semiconductor device, a semiconductor device, and a method for manufacturing a semiconductor device.

### BACKGROUND ART

In recent years, the development of clean energy has been desired for solving global environmental issues such as the depletion of energy resources and the increase of CO₂ in the atmosphere, and photovoltaic power generation using especially solar cells among the semiconductor devices has been researched as a new energy source. The photovoltaic power generation has been put into practical use and however still under development.

Conventionally, it is common that a bifacial electrode solar cell is used as a solar cell. The bifacial electrode solar cell is manufactured in the following manner: a pn junction is formed on a light-receiving surface of a monocrystalline or polycrystalline silicon substrate through diffusing impurities of a conductive type opposite to the conductive type of the silicon substrate into the light-receiving surface of the silicon substrate, and thereafter, an electrode is formed respectively on the light-receiving surface of the silicon substrate and the back surface opposite to the light-receiving surface (for example, see Japanese Patent Laying-Open No. 2007-234884 (PTD 1)). Generally, it is known that in the bifacial electrode solar cell, diffusing the impurities having the same conductive type as the silicon substrate at a high concentration into the back surface of the silicon substrate could achieve a higher output due to a back surface field effect.

Further, research and development are being made on such a back electrode solar cell that has an electrode formed only on the back surface without any electrode formed on the light-receiving surface of the silicon substrate (for example, see Japanese Patent Laying-Open No. 2006-332273 (PTD 2)).

Hereinafter, a method for manufacturing a bifacial electrode solar cell in the prior art will be described with reference to schematic cross sectional views in FIGS. 12(a) to 12(f).

First, as illustrated in FIG. 12(a), a p-type silicon substrate 100 is prepared. Then, as illustrated in FIG. 12(b), by diffusing phosphorus, which serves as an n-type dopant, to the entire surface of p-type silicon substrate 100, an n-type dopant diffusion layer 200 is formed on the entire surface of p-type silicon substrate 100.

Next, as illustrated in FIG. 12(c), n-type dopant diffusion layer 200 formed on the entire surface of p-type silicon substrate 100 is removed partially, leaving only the part of n-type dopant diffusion layer 200 on the surface which serves as a light-receiving surface of p-type silicon substrate 100. The removal of n-type dopant diffusion layer 200 may be performed in the following manner: after the light-receiving surface of p-type silicon substrate 100 formed with n-type dopant diffusion layer 200 is protected by a resist, and the other part of n-type dopant diffusion layer 200 which is not protected by the resist is removed through an etching process, and thereafter, the remained resist is removed by using an organic solvent or the like.

Subsequently, as illustrated in FIG. 12(d), a silicon nitride film 300, which functions as an antireflection film, is formed on n-type dopant diffusion layer 200 on the surface of p-type silicon substrate 100. Silicon nitride film 300 may be formed by using a low-pressure thermal CVD method or a plasma CVD method.

Next, as illustrated in FIG. 12(e), an aluminum paste 600 and a back surface silver paste 700 are formed through screen printing at desired locations on the back surface opposite to the light-receiving surface of p-type silicon substrate 100 and dried thereafter, and meanwhile, a silver paste 800 is formed through screen printing at desired locations on the surface of silicon nitride film 300 and dried thereafter.

Thereafter, as illustrated in FIG. 12(f), p-type silicon substrate 100 is fired in a near-infrared furnace under a dry air atmosphere at 800° C. to 850° C. for several minutes to less than 20 minutes to form a light-receiving surface silver electrode 801 on n-type dopant diffusion layer 200 on the light-receiving surface of p-type silicon substrate 100, and to form a back surface aluminum electrode 601 and a back surface silver electrode 701 on the back surface of p-type silicon substrate 100.

On the side of the light-receiving surface of p-type silicon substrate 100, during firing, silver paste 800 is fired through silicon nitride film 300 to be formed into light-receiving surface silver electrode 801 in electrical contact with n-type dopant diffusion layer 200 on the surface of p-type silicon substrate 100 and after firing.

On the side of the back surface of p-type silicon substrate 100, during firing, aluminum which serves as a p-type dopant is diffused from aluminum paste 600 into the back surface of p-type silicon substrate 100 to form a p-type dopant diffusion layer 900 on the back surface of p-type silicon substrate 100, and after firing, aluminum paste 600 is formed into back surface aluminum electrode 601, and back surface silver paste 700 is formed into back surface silver electrode 701.

FIG. 13 illustrates a schematic plan view of the back surface of a bifacial electrode solar cell of the prior art fabricated as described above. As illustrated in FIG. 13, in the back surface of the bifacial electrode solar cell of the prior art, two strips of back surface silver electrodes 701 are formed extending in a certain direction and separated with an interval therebetween.

### CITATION LIST

### Patent Document

### PTD 1: Japanese Patent Laying-Open No. 2007-234884

### PTD 2: Japanese Patent Laying-Open No. 2006-332273

### SUMMARY OF INVENTION

### Technical Problem

In the bifacial electrode solar cell of the prior art, after back surface silver paste 700 is coated and fired thereafter, back surface silver electrode 701 may shrink, which may cause an end portion 701a of back surface silver electrode 701 of the strip shape illustrated in FIG. 13 to curl inward, and thereby, it is not possible to manufacture the bifacial electrode solar cell at high manufacturing efficiency. In addition, it is desired that a bifacial electrode solar cell should have perfect electrical characteristics, solderability (connection strength when soldering the electrode to joint with the other members such as an interconnector and the like) and reliability.

The abovementioned problem is not only present in a bifacial electrode solar cell but also common in the other semiconductor devices.

In view of the aforementioned problems, an object of the present invention is to provide a conductive paste, an electrode for a semiconductor device, a semiconductor device and a method for manufacturing a semiconductor device capable of manufacturing a semiconductor device with perfect electrical characteristics, solderability and reliability at high manufacturing efficiency while preventing an end portion of an electrode from curling due to the shrinkage of the electrode originated from firing.

### Solution to Problem

The present invention provides a conductive paste including conductive powder made of a plurality of conductive particles, and silver powder made of a plurality of silver particles. The conductive particles includes a base material made of ceramics and a conductive layer configured to cover at least a part of an outer surface of the base material. The ratio of the mass of the conductive layer relative to the total mass of the conductive particles is 10% or more by mass, and the ratio of the mass of the conductive powder relative to the total mass of the conductive powder and the silver powder is 25% or less by mass.

Preferably, in the conductive paste of the present invention, the ratio of the mass of the conductive layer relative to the total mass of the conductive particles is 40% or less by mass.

Preferably, in the conductive paste of the present invention, the ratio of the mass of the conductive powder relative to the total mass of the conductive powder and the silver powder is 5% or more by mass.

Preferably, in the conductive paste of the present invention, the ceramics contains at least one selected from a group consisting of ferrite, silica and alumina.

The present invention provides an electrode for a semiconductor device manufactured by firing the abovementioned conductive paste.

The present invention provides a semiconductor device including a semiconductor substrate and the abovementioned electrode for a semiconductor device which is disposed on the semiconductor substrate.

The present invention provides a method for manufacturing a semiconductor device including the steps of applying the abovementioned conductive paste on the semiconductor substrate and firing the conductive paste.

### Advantageous Effects of Invention

According to the present invention, it is possible to provide a conductive paste, an electrode for a semiconductor device, a semiconductor device and a method for manufacturing a semiconductor device capable of manufacturing a semiconductor device with perfect electrical characteristics, solderability and reliability at high manufacturing efficiency while preventing an end portion of an electrode from curling due to the shrinkage of the electrode originated from firing.

### BRIEF DESCRIPTION OF DRAWINGS

FIG. 1(a) to (h) are schematic cross sectional views illustrating a method for manufacturing a solar cell according to Embodiment 1;

FIG. 2 is a schematic cross sectional view illustrating an example of a conductive paste applied to a surface of a p-type silicon substrate;

FIG. 3 is a schematic cross sectional view illustrating an example of conductive particles contained in the conductive paste;

FIG. 4 is a schematic plan view illustrating a light-receiving surface of the solar cell according to Embodiment 1;

FIG. 5 is a schematic plan view illustrating a back surface of the solar cell according to Embodiment 1;

FIG. 6 is a schematic perspective view illustrating a step of an example of a method for manufacturing a solar cell module using the solar cell according to Embodiment 1;

FIG. 7 is a schematic perspective view illustrating another step of an example of the method for manufacturing a solar cell module using the solar cell according to Embodiment 1;

FIG. 8 is a schematic perspective view illustrating another step of an example of the method for manufacturing a solar cell module using the solar cell according to Embodiment 1;

FIG. 9 is a schematic perspective view illustrating another step of an example of the method for manufacturing a solar cell module using the solar cell according to Embodiment 1;

FIG. 10 is a schematic cross sectional view illustrating an example of a solar cell module using the solar cell according to Embodiment 1;

FIG. 11 is a schematic side view illustrating a configuration example after an aluminum frame and the like are assembled to the solar cell module in FIG. 10;

FIG. 12(a) to (f) are schematic cross sectional views illustrating a method for manufacturing a bifacial electrode solar cell according to the prior art; and

FIG. 13 is a schematic plan view illustrating a back surface of the bifacial electrode solar cell according to the prior art.

### DESCRIPTION OF EMBODIMENTS

Hereinafter, embodiments of the present invention will be described. It should be noted that the same reference marks in the drawings of the present invention denotes the same or equivalent portions.

### Embodiment 1

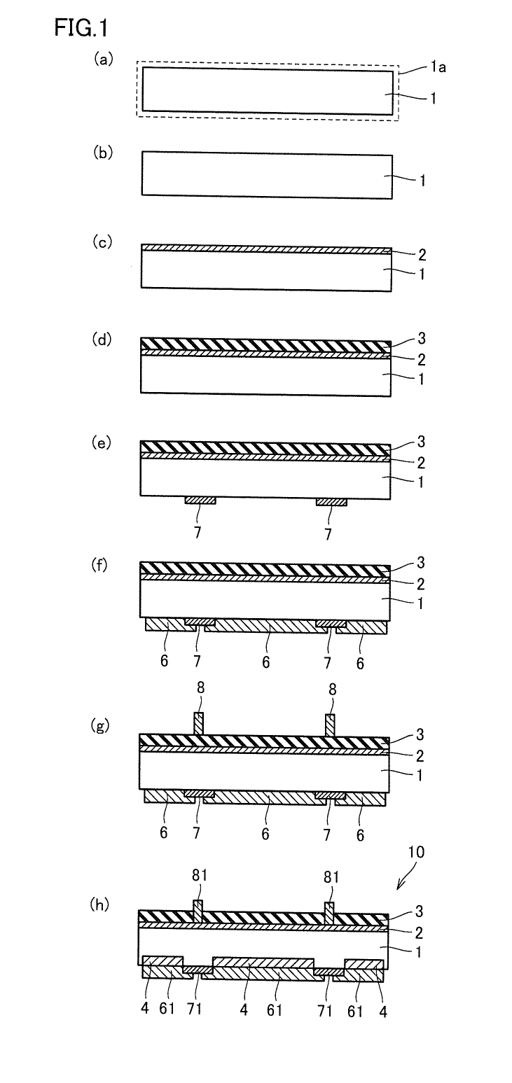

FIG. 1(a) to (h) are schematic cross sectional views illustrating a method for manufacturing a solar cell according to Embodiment 1.

First, as illustrated in FIG. 1(a), a p-type monocrystalline or polycrystalline silicon ingot is sliced by, for example, a wire saw or the like to offer a p-type silicon substrate 1. In slicing the abovementioned silicon ingot, a damaged layer 1a is formed on the entire surface of p-type silicon substrate 1.

Then, as illustrated in FIG. 1(b), the entire surface of p-type silicon substrate 1 is etched so as to remove damaged layer 1a formed on the entire surface of p-type silicon substrate 1. Here, by adjusting etching conditions, it is also possible to form minute asperities such as textures on the surface of p-type silicon substrate 1. In the case where the minute asperities are formed on the surface of p-type silicon substrate 1, it is possible to reduce the reflection of sunlight incident on the surface of p-type silicon substrate 1 formed with minute asperities, making it possible to increase the conversion efficiency of the solar cell.

Next, as illustrated in FIG. 1(c), an n-type dopant diffusion layer 2 is formed on one principal surface (hereinafter referred to as “first principal surface”) in two principal surfaces having the largest area among the surfaces of p-type silicon substrate 1. Here, n-type dopant diffusion layer 2 may be formed by using a method such as vapor phase diffusion of a gas containing phosphorus which serves as an n-type dopant such as POCl₃ or coating and diffusion of a dopant solution containing a phosphorus compound. In the case where the diffusion of phosphorus causes a phosphorus silicate glass layer to be formed on the first principle surface of p-type silicon substrate 1, the phosphorus silicate glass layer may be removed according to, for example, an acid treatment.

Subsequently, as illustrated in FIG. 1(d), an antireflection film 3 is formed on n-type dopant diffusion layer 2 on the first principle surface of p-type silicon substrate 1. Here, antireflection film 3 may be formed according to, for example, a method of forming a silicon nitride film by using a plasma CVD method or a method of forming a titanium oxide film by using an atmospheric pressure CVD method.

Next, as illustrated in FIG. 1(e), a conductive paste 7 is applied to a second principle surface opposite to the first principle surface of p-type silicon substrate 1, and dried thereafter.

Instead of a conventional silver paste, a paste in which at least a part of silver powder in the conventional silver paste is replaced by conductive power which is cheaper than the silver powder is used as conductive paste 7.

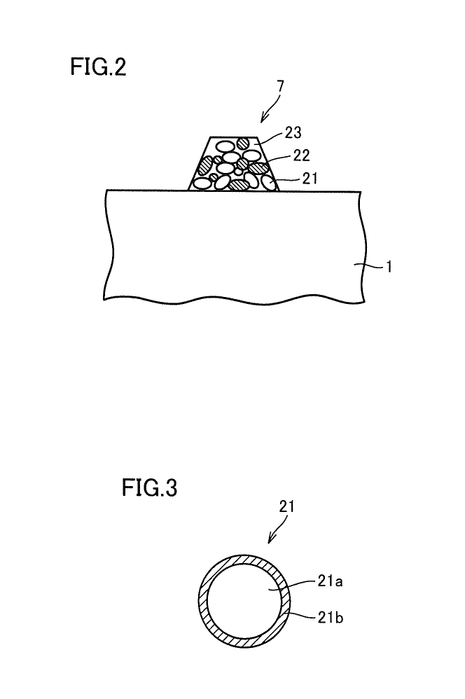

FIG. 2 is a schematic cross sectional view illustrating an example of conductive paste 7 applied to a surface of p-type silicon substrate 1. Conductive paste 7 contains conductive powder made of a plurality of conductive particles 21, silver powder made of a plurality of silver particles 22, and the other ingredient 23.

FIG. 3 is a schematic cross sectional view illustrating an example of conductive particles 21 contained in conductive paste 7. Conductive particles 21 includes a base material 21a made of ceramic and a conductive layer 21b which is electrically conductive and configured to cover at least a part of the outer surface of base material 21a made of ceramics.

Although ceramics constituting base material 21a is not limited in particular, it is preferable for it to contain at least one selected from a group consisting of ferrite, silica and alumina. Thereby, it is possible to prevent effectively an end portion of an electrode formed by firing conductive paste 7 from curling due to the shrinkage of the electrode originated from firing.

As conductive layer 21b, for example, it is possible to use an electrically conductive material such as silver. As a method of coating conductive layer 21b on at least a part of the outer surface of base material 21a made of ceramics, a non-electrolytic plating, for example, may be used.

In conductive paste 7 illustrated in FIG. 2, the ratio of the mass of conductive layer 21b relative to the total mass of conductive particles 21 is 10% or more by mass, and the ratio of the mass of the conductive powder relative to the total mass of the conductive powder and the silver powder is 25% or less by mass. Thereby, it is possible to prevent effectively an end portion of an electrode formed by firing conductive paste 7 from curling due to the shrinkage of the electrode originated from firing, making it possible to manufacture a solar cell with perfect electrical characteristics, solderability and reliability at high manufacturing efficiency.

Preferably, the ratio of the mass of conductive layer 21b relative to the total mass of conductive particles 21 is 40% or less by mass. In the case where the ratio of the mass of conductive layer 21b relative to the total mass of conductive particles 21 is greater than 40% by mass, there is a possibility that F.F (Fill Factor) and reliability of the solar cell will decrease, and the solderability of the electrode formed after firing conductive paste 7 will become worse.

Preferably, the ratio of the mass of the conductive powder relative to the total mass of the conductive powder and the silver powder is 5% or more by mass. In the case where the ratio of the mass of the conductive powder relative to the total mass of the conductive powder and the silver powder is less than 5% by mass, there is a possibility that F.F (Fill Factor) and reliability of the solar cell will decrease, and the solderability of the electrode formed after firing conductive paste 7 will become worse.

As the other ingredient 23, for example, it is possible to use a substance such as glass frit, resin, an additive, an organic solvent and/or the like used in the conventional silver paste.

Conductive paste 7 having the abovementioned composition may be prepared according to a method publicly known in the prior art by mixing the conductive powder made of the plurality of conductive particles 21, the silver powder made of the plurality of silver particles 22, and the other ingredient 23.

Thereafter, as illustrated FIG. 1(f), an aluminum paste 6 is applied to the second principal surface of p-type silicon substrate 1, and dried thereafter. As aluminum paste 6, for example, it is possible to use a publicly known substance containing such as aluminum powder, glass frit, resin, an additive, an organic solvent and/or the like. As a method of applying aluminum paste 6, for example, the screen printing may be used.

Next, as illustrated FIG. 1(g), a silver paste 8 is applied to antireflection film 3 on the first principal surface of p-type silicon substrate 1, and dried thereafter. As silver paste 8, for example, it is possible to use a publicly known substance containing such as silver powder, glass frit, resin, an additive, an organic solvent and/or the like. As a method of applying silver paste 8, for example, the screen printing may be used.

Thereafter, as illustrated FIG. 1(h), aluminum paste 6, conductive paste 7 and silver paste 8 are fired to form an aluminum electrode 61 and a back surface electrode 71 on the second principal surface of p-type silicon substrate 1, and a light-receiving surface silver electrode 81 on the first principal surface of p-type silicon substrate 1.

Specifically, aluminum electrode 61 on the second principal surface of p-type silicon substrate 1 is formed by firing aluminum paste 6, and back surface electrode 71 thereon is formed by firing conductive paste 7.

Light-receiving surface silver electrode 81 on the first principal surface of p-type silicon substrate 1 is formed by firing silver paste 8.

A p-type dopant diffusion layer 4 is formed on the second principal surface of p-type silicon substrate 1 by diffusing aluminum contained in aluminum paste 6 into the second principal surface of p-type silicon substrate 1 during firing.

Specifically, during firing, silver paste 8 is fired through antireflection protection film 3 so as to form light-receiving surface silver electrode 81 in electric connection with n-type dopant diffusion layer 2. In the manner as described above, it is possible to manufacture a solar cell 10 according to Embodiment 1.

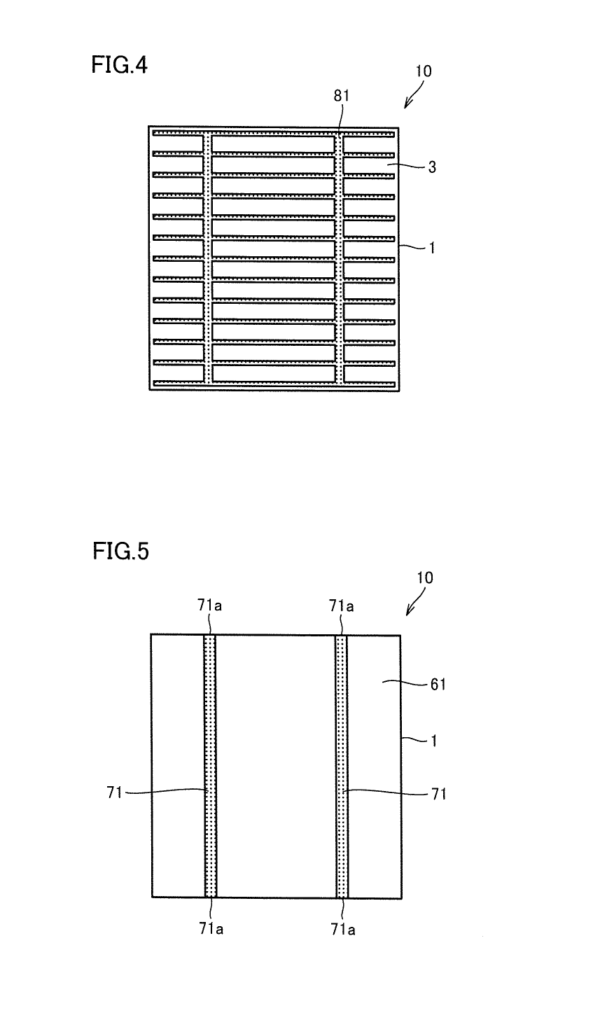

FIG. 4 is a schematic plan view illustrating a light-receiving surface of solar cell 10 according to Embodiment 1, and FIG. 5 is a schematic plan view illustrating a back surface of solar cell 10 according to Embodiment 1.

As illustrated in FIG. 4, light-receiving surface silver electrode 81 on the light-receiving surface of solar cell 10 according to Embodiment 1 is formed into a lattice shape. As illustrated in FIG. 5, back surface electrode 71 on the back surface of solar cell 10 according to Embodiment 1 is formed into a strip shape.

In the step of forming back surface electrode 71 by firing conductive paste 7, since conductive paste 7 is heated to a temperature below the melting temperature of conductive particles 21 (and silver particles 22) contained in conductive paste 7, back surface electrode 71 is formed into a solid structure through consolidating the aggregation of conductive particles 21 (and silver particles 22) without melting the same.

Thus, even in the case where electrically insulating ceramics is used as base material 21a of conductive particles 21 contained in conductive paste 7, the electricity can be conducted through conductive layer 21b, which is electrically conductive, on the outer surface of base material 21a of the conductive particles 21, and thereby, it is possible to ensure the electrical conductivity of back surface electrode 71.

Moreover, since back surface electrode 71 formed by firing conductive paste 7 possesses the electrode property approximately equivalent to the silver electrode formed by firing the silver paste containing no conductive paste 7, it is possible to prevent the series resistance between back surface electrode 71 and the second principle surface of p-type silicon substrate 1 from rising.

Further, in the present embodiment, since back surface electrode 71 is formed by firing conductive paste 7 having the composition described above, it is possible to prevent an electrode end portion 71a from curling due to the shrinkage of electrode 71 originated from firing, making it possible to manufacture solar cell 10 with perfect electrical characteristics, solderability and reliability at high manufacturing efficiency.

Furthermore, it is possible to manufacture a solar cell module using solar cell 10 according to Embodiment 1 described above in the following manner, for example.

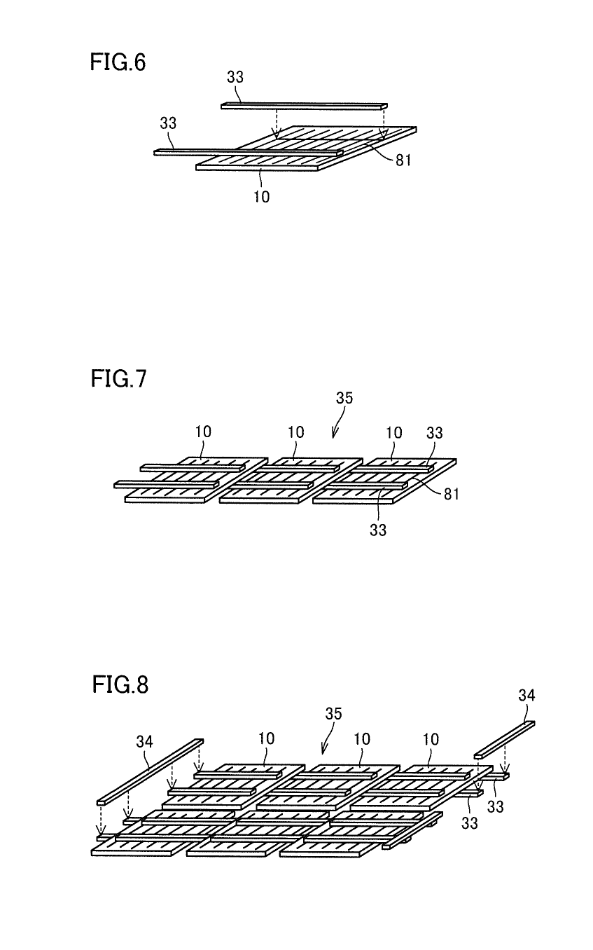

First, as illustrated in the schematic perspective view of FIG. 6, one end of an interconnector 33 which is an electrically conductive member is connected to light-receiving surface silver electrode 81 of solar cell 10 according to Embodiment 1.

Next, as illustrated in the schematic perspective view of FIG. 7, a plurality of solar cells 10 each disposed with interconnector 33 are arranged in a row, and the other end of interconnector 33 being connected to light-receiving surface silver electrode 81 of one solar cell 10 is sequentially connected to back surface electrode 71 on the back surface of another adjacent solar cell 10, and thereby, a solar cell string 35 is fabricated.

Subsequently, as illustrated in the schematic perspective view of FIG. 8, a plurality of solar cell strings 35 are arranged in column, interconnectors 33 protruding respectively from both ends of one solar cell string 35 and interconnectors 33 protruding respectively from both ends of another adjacent solar cell string 35 are connected using a wiring member 34 which is electrically conductive, and thereby, solar cell strings 35 adjacent to each other are connected in series.

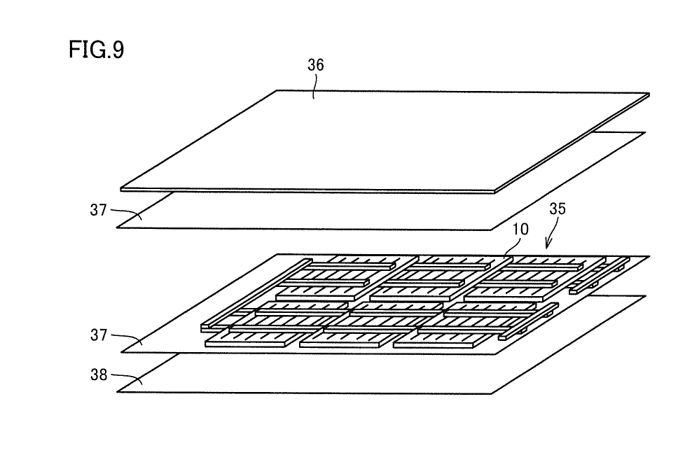

Thereafter, as illustrated in the schematic perspective view of FIG. 9, solar cell strings 35 connected according to the abovementioned manner is sealed by a sealing material 37 such as EVA (ethylene vinyl acetate), and is thereafter sandwiched between a transparent substrate 36 such as a glass substrate and a back surface protective sheet 38 such as a PET (polyethylene terephthalate) film. Thereby, it is possible to fabricate a solar cell module using solar cell 10 according to Embodiment 1.

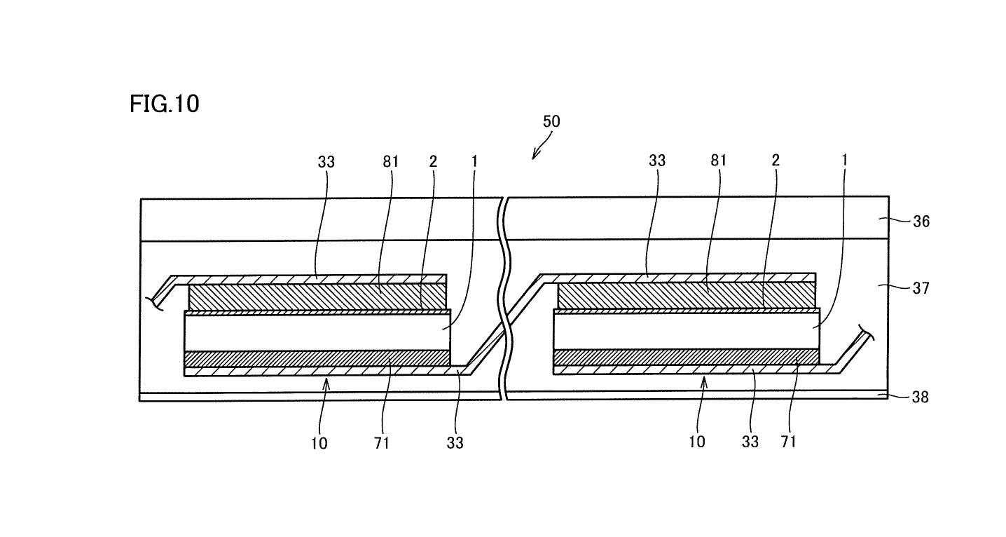

FIG. 10 is a schematic cross sectional view illustrating an example of a solar cell module 50 fabricated in the abovementioned manner by using solar cell according to Embodiment 1. In solar battery module 50 of FIG. 10, solar cells 10 are sealed in sealing member 37 which is sandwiched between transparent substrate 36 and back side protective sheet 38. One end of interconnector 33 is electrically connected to light-receiving surface silver electrode 81 of solar cell 10, and the other end of interconnector 33 is electrically connected to back surface electrode 71 on the back surface of solar cell 10.

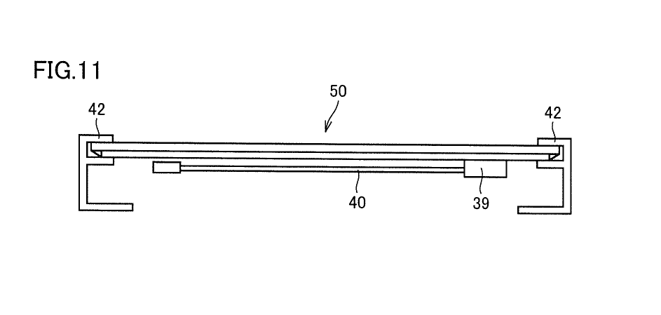

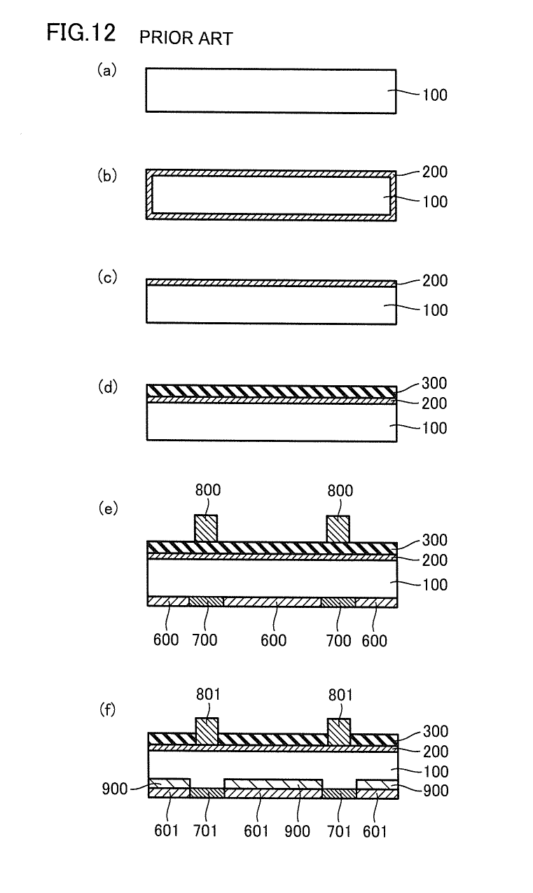

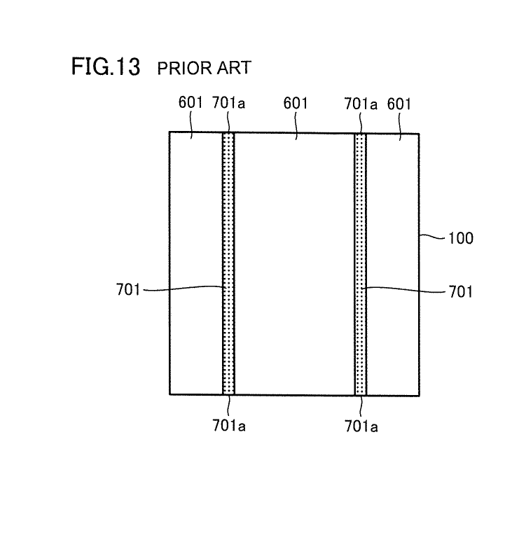

As illustrated in the schematic side view of FIG. 11, an aluminum frame 42 may be attached around solar cell module 50 having the structure illustrated in FIG. 10, and a terminal box 39 having a cable 40 may be attached to the back surface of solar cell module 50.

It should be noted that although in the above a p-type silicon substrate is used as the semiconductor substrate of a solar cell, any semiconductor substrate other than the p-type silicon substrate may be used.

### Examples

### Fabrication of Solar Cells of Sample No. 1 to 9

First, a p-type polycrystalline silicon substrate with two principal surfaces in the shape of a square having a side length of 156 mm was prepared in a thickness of 200 μm. Specifically, the p-type polycrystalline silicon substrate was prepared in such a way that a p-type polycrystalline silicon ingot was sliced by using a wire saw, and thereafter, a damaged layer on the surface was removed through etching in an alkaline solution.

Then, after a phosphorus silicate glass solution (PSG solution) was applied to one principle surface of the p-type polycrystalline silicon substrate, the p-type polycrystalline silicon substrate was placed in a temperature atmosphere of about 900° C. to form an n-type dopant diffusion layer on the one principle surface of the crystalline silicon substrate through diffusion of phosphorus. Here, the sheet resistance of the n-type dopant diffusion layer was about 50 Ω/sq.

Thereafter, a silicon nitride film having a thickness of 80 nm was formed by using the plasma CVD method on the n-type dopant diffusion layer on the principle surface of the p-type polycrystalline silicon substrate.

In the manner described above, a plurality of p-type polycrystalline silicon substrates each having a silicon nitride film formed on one principle surface thereof were fabricated. Thereafter, conductive pastes of sample No. 1 to 9 were applied respectively to a part of the other principle surface of each of the p-type polycrystalline silicon substrates opposite to the principle surface formed with the silicon nitride film in two lines through screen printing, and after that, commercially available aluminum pastes were applied respectively to substantially the entire surface of the principle surface of each of the p-type silicon substrates in a way of overlapping partially with the conductive paste. Thereafter, the conductive paste, the silver paste and the aluminum paste applied to the principle surface of each of the p-type polycrystalline silicon substrates were dried at a temperature atmosphere of about 150° C.

The conductive pastes of sample No. 1 to 9 were prepared respectively in the following manner. First, the conductive powder containing a plurality of conductive particles with silver coated on the outer surface of an alumina base material at the amount of coated silver listed in Table 1 was mixed with the silver powder made of a plurality of silver particles by the ratio of the conductive powder listed in Table 1 to form a powder mixture. The amount of coated silver listed in Table 1 denotes the ratio of the mass of coated silver relative to the total mass of the conductive particles. The ratio of the conductive powder listed in Table 1 denotes the ratio of the mass of the conductive powder relative to the total mass of the conductive powder and the silver powder.

As the conductive powder for preparing the conductive pastes of sample No. 1 to 9, the conductive powder made of conductive particles having a conductive layer made of silver coated on the entire outer surface of a plate-shaped alumina substrate having rectangular surfaces, which is manufactured by the ECKA company, was used. The median diameter (D50) of the conductive particles in the conductive powder for preparing the conductive pastes of sample No. 1 to 9 was 7 μm.

Then, the powder mixture described in the above was kneaded with glass frit made of borosilicate lead glass, resin made of ethyl cellulose and a solvent made of butyl carbitol acetate in a mixer and dispersed thereafter with three rollers to prepare the conductive pastes of sample No. 1 to 9. The mixing ratio (mass ratio) of the powder mixture, the glass frit, the resin and the solvent in each of the conductive pastes of sample No. 1 to 9 was the powder mixture:glass frit:resin and solvent=78:1.6:20.4. The viscosity of each of the conductive pastes of sample No. 1 to 9 was about 170 Pa·s (measured by using a viscometer manufactured by Brookfield Co. at a rotational speed of 10 rpm).

Next, after the silver paste was printed through screen printing into the lattice shape on the silicon nitride film on one principle surface of each p-type polycrystalline silicon substrate, the silver paste applied to the silicon nitride film on the principle surface of each p-type polycrystalline silicon substrate was dried at a temperature atmosphere of about 150° C.

Subsequently, the silver paste applied to one principle surface of each p-type polycrystalline silicon substrate, and the conductive paste and the aluminum paste applied to the other principle surface of each p-type polycrystalline silicon substrate were fired at a temperature of 860° C. in air.

Accordingly, the silver electrode (light-receiving surface electrode) was formed on one principle surface of the p-type polycrystalline silicon substrate. The silver electrode was a fired product of the silver paste which is obtained by firing the silver paste through the silicon nitride film in electric connection to the n-type dopant diffusion layer. Meanwhile, the p-type dopant diffusion layer was formed through diffusion of aluminum from the aluminum paste on the other principle surface of the p-type polycrystalline silicon substrate, together with the aluminum electrode which is a fired product of the aluminum paste and the linear silver electrode (back surface electrode having the shape of back surface electrode 71 in FIG. 5) which is a fired product of the conductive paste.

Thereby, the solar cells of sample No. 1 to 9, each having a light-receiving surface electrode made of the silver electrode and a back surface electrode made of the silver electrode and the aluminum electrode on the back surface, were fabricated. The solar cells of sample No. 1 to 9 corresponds to the solar cells, each of which is formed with the back surface electrode using the conductive pastes of sample No. 1 to 9, respectively.

<Evaluation of Electrical Characteristics>

Hereinafter, for each of the solar cells of sample No. 1 to 9 fabricated as described above, after the principle surface disposed with the back electrode was entirely adsorbed on a conductive stage, the current-voltage characteristics of each of the solar cells of sample No. 1 to 9 were measured by directing a beam of pseudo sunlight to the principle surface disposed with the light-receiving surface electrode so as to calculate the F.F. Meanwhile, for the purpose of comparison, the comparative solar cells were fabricated in the same manner except that a silver paste was used to replace each of the conductive pastes of sample No. 1 to 9, and the current-voltage characteristics of each of the comparative solar cells were measured to calculate the F.F. Thereafter, the ratio of the F.F of each of the solar cells of sample No. 1 to 9 relative to the F.F of each of the comparative solar cells was calculated and evaluated according to the following evaluation criteria. The result is shown in the column of electrical characteristics of Table 1.

<Evaluation Criteria of Electrical Characteristics>

A: the F.F of each of the solar cells of sample No. 1 to 9 is 99% or more of the F.F of each of the comparative solar cells, and

B: the F.F of each of the solar cells of sample No. 1 to 9 is less than 99% of the F.F of each of the comparative solar cells.

<Evaluation of Solderability>

A tab, which is made of copper having a width of 2 mm and coated with Sn—Ag solder, was soldered to the surface of the back electrode of each of the solar cells of sample No. 1 to 9, and the tab was thereafter pulled in the direction of an angle of 45° formed between the tab and the surface of the back surface electrode. The evaluation was performed according to the following evaluation criteria. The result is shown in the column of solderability of Table 1.

<Evaluation Criteria of Solderability>

A: tensile strength is 200 g or more, and after the tab is stripped off, the stripped surface is in the interface between the back surface electrode and the p-type polycrystalline silicon substrate or inside the p-type polycrystalline silicon substrate,

B: tensile strength is 200 g or more, and after the tab is stripped off, the stripped surface is in the interface between the tab and the back surface electrode or inside the back surface electrode,

C: tensile strength is less than 200 g, and

D: the tab is not attached thereto.

<Evaluation of Reliability>

After a tab which is made of copper having a width of 2 mm and coated with Sn—Ag solder was soldered to the surface of the back electrode of each of the solar cells of sample No. 1 to 9, it was allowed to stand in an atmosphere of 85% relative humidity for 500 hours, and thereafter, similar to the above, the F.F of each of the solar cells of sample No. 1 to 9 was calculated. Then, the ratio of the F.F of each of the solar cells of sample No. 1 to 9 relative to the F.F of each of the comparative solar cells was calculated and evaluated according to the following evaluation criteria. The result is shown in the column of reliability of Table 1. The sign “−” in the column of reliability of Table 1 denotes that the corresponding determination was not performed.

<Evaluation Criteria of Reliability>

A: the F.F of each of the solar cells of sample No. 1 to 9 is 95% or more of the F.F of each of the comparative solar cells, and

B: the F.F of each of the solar cells of sample No. 1 to 9 is less than 95% of the F.F of each of the comparative solar cells.

<Evaluation of Volume Shrinkage Rate>

During the fabrication of each of the solar cells of sample No. 1 to 9, the volume (V_{dry}) of the screen-printed conductive paste after drying was measured, and thereafter, the volume (V_{fir}) of the back surface electrode fabricated by firing the conductive paste was measured. Then, the ratio (V_{fir}/V_{dry}) of the volume (V_{fir}) of the back surface electrode fabricated by firing the conductive paste relative to the volume (V_{dry}) of the screen-printed conductive paste after drying was calculated as the volume shrinkage rate (sample). In the same manner, the volume shrinkage rate (comparative) of each of the comparative solar cells was calculated. The volume shrinkage rate (sample) was divided by the volume shrinkage rate (comparative) and multiplied by 100, the obtained value is shown in the column of volume shrinkage rate of Table 1. The greater the value in the column of volume shrinkage rate of Table 1 is, the better the shrinkage of the back surface electrode is suppressed. The sign “−” in the column of volume shrinkage rate of Table 1 denotes that the corresponding determination was not performed.

TABLE 1

| | Conductive Paste | | Evaluation | | | |
|---|---|---|---|---|---|---|
| Sample | Amount of Coated Silver | Ratio of Conductive Powder | Electrical | | | Volume Shrinkage |
| No. | (% by mass) | (% by mass) | Characteristics | Solderability | Reliability | Rate (%) |
| 1 | 10 | 5 | A | A | A | 101 |
| 2 | 20 | 5 | A | A | A | 104 |
| 3 | 20 | 15 | A | A | A | 108 |
| 4 | 20 | 25 | A | A | A | 113 |
| 5 | 20 | 35 | A | B | B | 119 |
| 6 | 40 | 5 | A | A | A | 102 |
| 7 | 40 | 15 | A | A | A | 103 |
| 8 | 40 | 25 | A | A | A | 109 |
| 9 | 40 | 35 | A | B, C | — | 114 |

<Evaluation Results>

As shown in Table 1, it was confirmed that the solar cells of sample No. 1 to 4 and 6 to 8 having the amount of coated silver on the conductive particles at 10% or more by mass to 40% or less by mass and the ratio of conductive powder at 5% or more by mass to 25% or less by mass have perfect electrical characteristics, solderability and reliability, and the shrinkage of the back surface electrode thereof is suppressed. The solar cells of sample No. 5 and 9 had the shrinkage of the back surface electrode thereof suppressed but lacked perfect solderability and reliability.

It should be understood that the embodiments disclosed herein have been presented for the purpose of illustration and description but not limited in all aspects. It is intended that the scope of the present invention is not limited to the description above but defined by the scope of the claims and encompasses all modifications equivalent in meaning and scope to the claims.

### INDUSTRIAL APPLICABILITY

The present invention is applicable to a conductive paste, an electrode for a semiconductor device, a semiconductor device, and a method for manufacturing a semiconductor device.

### REFERENCE SIGNS LIST

1: p-type silicon substrate; 1a: damaged layer; 2: n-type dopant diffusion layer; 3: antireflection film; 6: aluminum paste; 7: conductive paste; 8: silver paste; 10: solar cell; 21: conductive particles; 21a: base material; 21b: conductive layer; 22: silver particles; 23 other ingredient; 33: interconnector; 34: wiring member; 35: solar cell string; 36: transparent substrate; 37: sealing material; 38: back surface protective sheet; 39: terminal box; 40: cable; 42: aluminum frame; 50: solar cell module; 61: aluminum electrode; 71: back electrode; 71a: end portion; 81: light-receiving surface silver electrode; 100: p-type silicon substrate; 200: n-type dopant diffusion layer; 300: silicon nitride film; 600: aluminum paste; 601: back surface aluminum electrode; 700: back surface silver paste; 701: back surface silver electrode; 800: light-receiving surface silver paste; 801: light-receiving surface silver electrode; 900: p-type dopant diffusion layer

1. A conductive paste comprising:
conductive powder made of a plurality of conductive particles; and
silver powder made of a plurality of silver particles,
said conductive particles including a base material made of ceramics and a conductive layer configured to cover at least a part of an outer surface of said base material,
the ratio of the mass of said conductive layer relative to the total mass of said conductive particles is 10% or more by mass, and
the ratio of the mass of said conductive powder relative to the total mass of said conductive powder and said silver powder is 25% or less by mass.

2. The conductive paste according to claim 1, wherein the ratio of the mass of said conductive layer relative to the total mass of said conductive particles is 40% or less by mass.

3. The conductive paste according to claim 1, wherein the ratio of the mass of said conductive powder relative to the total mass of said conductive powder and said silver powder is 5% or more by mass.

4. The conductive paste according to claim 1, wherein said ceramics contains at least one selected from a group consisting of ferrite, silica and alumina.

5. An electrode for a semiconductor device manufactured by firing a conductive paste according to claim 1.

6. A semiconductor device comprising:
a semiconductor substrate; and
an electrode for a semiconductor device according to claim 5 which is disposed on said semiconductor substrate.

7. A method for manufacturing a semiconductor device, comprising the steps of:
applying a conductive paste according to claim 1 on a semiconductor substrate; and
firing said conductive paste.
